(19) United States
(12) Patent Application Publication
(10) Pub. No.: US 2009/0245526 A1
(43) Pub. Date: Oct. 1, 2009

(54) DEVICE FOR AND METHOD OF ADDING REVERBERATION TO AN INPUT SIGNAL

(76) Inventors: Marc Klein Middelink, Eindhoven (NL); Leon Van De Kerkhof, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 11/574,734

(22) PCT Filed: Aug. 11, 2005
(86) PCT No.: PCT/IB05/52668

§ 371 Date: Mar. 6, 2007

(30) Foreign Application Priority Data
Sep. 8, 2004 (EP) 04104320.9

(51) Int. Cl. H03G 3/00

(52) U.S. Cl. 381/63

(57) ABSTRACT

A device (1) for adding reverberation to an input signal (s(n)) uses a corresponding transformed input signal (S(n)), for example the Fourier transform of the signal, to generate reverberation. The device comprises circuits (3, 5, 6) for combining the transformed input signal (S(n)) with a modified and delayed transformed output signal (G(Sr(n−i))) so as to produce a current transformed output signal (Sr(n)). Inversely transforming the current transformed output signal (Sr(n)) results in an output signal (sr(n)) having reverberation.

### FIELD OF THE INVENTION

The present invention relates to a device for and a method of adding reverberation to signals, in particular audio signals.

### BACKGROUND OF THE INVENTION

It is well known to add reverberation to audio signals to imitate the acoustic effects of a room, or of a concert hall. Reverberation may be generated electronically using a so-called delay line, an element which delays the audio signal over a certain time period by temporarily storing the signal samples in successive memory elements. However, to obtain a natural-sounding effect, very large delay lines are required. A typical reverberation time of 2 seconds requires a delay element that is 50,000 to 100,000 samples long, a size that is difficult and uneconomic to implement.

Various attempts have been made to overcome this problem. U.S. Pat. No. 5,917,917 (Jenkins), for example, suggests decimating the audio signal prior to applying the signal to a reverberation device, and subsequently interpolating the resulting signal to restore the sampling frequency. It will be clear that this approach is likely to introduce artifacts into the signal while still requiring a large delay line.

Alternative solutions suggest calculating the convolution of the audio signal and the impulse response of a room or concert hall to obtain reverberation. However, such impulse responses are typically long and the computational effort involved in such solutions is very large, while large memories are still necessary.

### SUMMARY OF THE INVENTION

It is an object of the present invention to overcome these and other problems of prior art and to provide a device and a method of adding reverberation to a signal, which device and method require substantially less memory and less computational effort.

Accordingly, the present invention provides a device for adding reverberation to an input signal represented by a corresponding transformed input signal, the device comprising delay means for delaying the transformed output signal so as to produce a delayed transformed output signal, and combination means for combining the transformed input signal with a delayed transformed output signal so as to produce a current transformed output signal representing an output signal having reverberation.

By using transformed signals instead of time signals, a very realistic reverberation effect can be obtained while avoiding the memory requirements and computational cost involved in calculating convolutions. Transforming the input signal can be carried out using standard optimized transformations, such as the Fast Fourier Transform (FFT).

In the present invention, the transformed output signal is based upon both the transformed input signal and a delayed version of the previous output signal. This delayed version of the previous output signal is preferably modified in amplitude and/or phase so as to be able to provide the desired reverberation.

The delay means are arranged for temporarily storing the output signal so as to produce the previous output signal. Typically, the delay means will store the signal for the duration of one frame, in which case the term “previous” is understood to mean, “immediately preceding”. However, the invention is not so limited and the delay means may also store the signal for the duration of two or more frames, in which case the term “previous” is understood to mean “existing before in time or order”. The delay means may be constituted by means of a memory unit, a suitable register, or other delay unit.

It is noted that a frame is typically understood to comprise a set of signal samples, for instance 256, 512 or 1024 samples, which are together subjected to a transformation such as the Fast Fourier Transform (FFT). Depending on the sampling frequency, a frame may represent certain time duration. At a sampling speed of 44.1 kHz, for example, a frame of 1024 samples has duration of approximately 23.2 ms.

In a preferred embodiment, the device of the present invention comprises modification means for modifying the amplitude and/or the phase of the delayed transformed output signal so as to produce a modified and delayed transformed output signal. The delayed transformed output signal, which is used to produce a new output signal, is preferably modified before being combined with the (new) transformed input signal. This modification may comprise an amplitude modification by applying a gain (or attenuation), but more importantly comprises a phase modification.

In particular, the present invention proposes to modify the phase of the transformed delayed output signal such that its phase changes randomly or pseudo-randomly. This substantially random phase modification avoids repetitive patterns in the reverberation. Such patterns would give rise to undesirable audible artifacts.

In a further advantageous embodiment, the random phase modification is bound by a maximum phase difference, said maximum phase difference being substantially smaller than p for low frequencies and substantially equal to p for high frequencies. That is, a frequency-dependent limit is imposed on the phase modification imparted by the modification means so as to avoid undesirable effects. While the random phase may fluctuate between −p and p rad for high frequencies (in a typical but non-limiting example, for frequencies higher than approximately 300 Hz), the random phase which may be added to the original phase is very small for low frequencies (in a typical but non-limiting example, for frequencies lower than approximately 100 Hz) in order not to distort low-frequency signal components.

As mentioned above, the modification unit may also apply a gain (or, if the gain is smaller than one, an attenuation) to the delayed transformed output signal in order to control the amplitude of the reverberation and, consequently, the reverberation time. In a preferred embodiment, the modification means are arranged for an amplitude modification that involves a relatively small attenuation for low frequencies and a relatively large attenuation for higher frequencies. The frequency-dependent attenuation allows a reverberation time, which is longer at lower frequencies and gradually decreases for higher frequencies. This corresponds with the reverberant behavior of typical rooms.

It is further preferred that the distinction between “low” and “high” frequencies is similar to that used for the phase. Using the above example, the attenuation may be relatively small for frequencies up to approximately 100 Hz and relatively high for frequencies from approximately 300 Hz. It will be understood that these values are exemplary only and that other values may be used, such as 1000 and 3000 Hz, without departing from the present invention.

In the above discussion it has been assumed that the device of the present invention receives a single input signal. The invention, however, is not so limited and also provides a device that is capable of receiving multiple input signals. In a particularly advantageous embodiment the device of the present invention comprises multiple parallel branches, each branch being provided with processing means for combining a partial transformed input signal with a modified and delayed transformed partial output signal so as to produce a current transformed partial output signal, the device further comprising at least one further combination unit for combining the transformed partial output signals into a transformed combined output signal. The partial transformed input signals may, for example, represent individual instruments in a musical instrument digital interface (MIDI) sound bank, or may each represent a sum of various instruments in a MIDI sound bank. The partial transformed input signals may be stored directly in a MIDI sound bank or may be synthesized in the frequency domain from a parametric representation of the audio signals in a MIDI sound bank.

Advantageously, at least one branch may comprise at least one scaling unit. The scaling unit allows the contribution from the branch to be controlled. In some embodiments, a branch may contain two scaling units, one for scaling the delayed transformed output signal, and one for scaling the transformed output signal itself. Advantageously, a scaling unit is incorporated in the modification means of each branch.

It is preferred that the processing means are arranged for processing the transformed input signal per frame. This allows the processing means to process a plurality of samples substantially simultaneously, thus increasing the processing speed. In addition, any transform unit typically operates on a set of samples simultaneously and using frames therefore facilitates this processing. It will be understood that the actual frame size used is not relevant, although sizes that are powers of two (such as 512 and 1024) are of course convenient in digital signal processing.

The at least one input signal may be received as a transformed input signal produced by an external transform unit or by a storage device on which transformed signals are stored. However, when the input signal is received as a time signal, the device of the present invention conveniently further comprises a transform unit for transforming an input signal into a transformed input signal. In case multiple time signals are received, multiple transform units may be provided. In addition, at least one A/D (analog/digital) converter may be provided in case the input signal is an analog signal. The device of the present invention may advantageously also comprise an inverse transform unit for transforming the current transformed output signal into a time signal.

Although the device of the present invention may be made up of distinct units, such as a combination unit and a delay (memory) unit, it is also possible for the device to be constituted by a microprocessor or a microcomputer executing suitable software instructions.

The present invention can also be said to provide a device for adding reverberation to an audio signal represented by its frequency spectrum, the device comprising delay means for delaying the frequency spectrum so as to produce a delayed frequency spectrum, modification means for modifying the phase of the delayed frequency spectrum so as to produce a phase-adjusted frequency spectrum, combination means for combining the phase-adjusted frequency spectrum with the original frequency spectrum so as to produce a combined frequency spectrum, and inverse transform means for inversely transforming the combined frequency spectrum so as to produce an audio signal having reverberation, wherein the modification means are arranged for providing a substantially random phase. The modification means may also be arranged for modifying the amplitude of the delayed frequency spectrum.

The present invention further provides an audio system comprising a device as defined above. Said audio system may be an electronic musical instrument, such as an electronic organ, a keyboard or a synthesizer, comprising a device as defined above, as well as a ring tone synthesizer, in particular for use in a mobile telephone or a gaming device, comprising a device according to the present invention.

The present invention additionally provides a method of adding reverberation to an input signal represented by a corresponding transformed input signal, the method comprising the steps of delaying the transformed output signal so as to produce a delayed transformed output signal, and combining the transformed input signal with a delayed transformed output signal so as to produce a current transformed output signal representing an output signal having reverberation.

The aspects defined above and further aspects of the invention are apparent from the examples of embodiment to be described hereinafter and are explained with reference to these examples of embodiment.

### BRIEF DESCRIPTION OF THE DRAWINGS

The present invention will further be explained below with reference to exemplary embodiments illustrated in the accompanying drawings, to which the invention is not limited.

FIG. 1 schematically shows a first embodiment of a device according to the present invention.

FIG. 2 schematically shows a second embodiment of a device according to the present invention.

FIG. 3 schematically shows an audio system, which incorporates a device according to the present invention.

FIG. 4 schematically shows an exemplary gain adjustment as used in the present invention.

FIG. 5 schematically shows an exemplary maximum phase adjustment as used in the present invention.

### DETAILED DESCRIPTION OF THE INVENTION

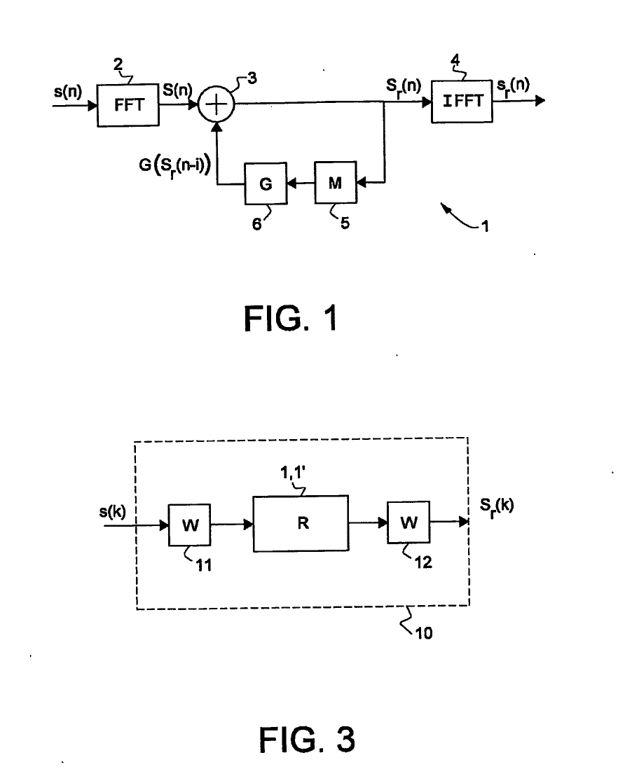

The reverberation device 1 shown merely by way of non-limiting example in FIG. 1 comprises a transform unit 2, a combination unit 3, an inverse transform unit 4, a memory unit 5, and a gain/phase modification unit 6.

In the present example, the transform unit 2 receives a time signal s(n). This time signal s(n) is digital (or digitized), with n indicating the frame number and each frame containing a number of samples. Those skilled in the art will understand that an A/D (Analog/Digital) converter should be provided in case an analog input signal is received. The time signal s(n) typically is an audio signal to which reverberation are to be added.

The transform unit 2 receives the time signal s(n) and outputs a transformed signal S(n). Typically, the transform unit 2 applies a Fast Fourier Transform (FFT), in which case the transformed signal S(n) is the frequency spectrum of the time signal s(n), with n again indicating the frame number and the frame now containing a number of frequency components.

Instead of the (Fast) Fourier Transform, other transforms, such as the (modified) cosine transform, may also be applied. It is further possible for the device 1 to receive the frequency spectrum S(n) instead of the time signal s(n), or to directly synthesize the frequency spectrum S(n) in the frequency domain from a parametric representation of the signal s(n), in which cases the transform unit 2 may be omitted. The transformed signal S(n) is fed to a combination unit 3, which in the embodiment shown is constituted by a signal adding circuit.

In the combination circuit 3, the transformed signal S(n) is combined with (that is, added to) a delayed and modified version of the transformed output signal Sr(n) to produce a new transformed output signal:

Sᵣ(n)=S(n)+G(Sᵣ(n−i)) (1)

where i indicates the amount of delay introduced by the memory (M) 5 and G indicates the gain and/or phase adjustment provided by the modification unit 6. The amount of delay is, in the present example, expressed in frames. A typical delay is equal to one frame (i=1), although delays of two, three or more frames are also possible, depending of the time duration of each frame and the desired reverberation or reverberation time. The gain and the phase adjustment, if any, may vary in time.

The memory unit 5, which serves as a delay unit, temporarily stores one or more frames of the transformed output signal Sr(n) to produce a signal Sr(n−i). A delayed frame is output to the modification unit 6 which modifies the phase and possibly also the gain of the transformed signal Sr(n−i) to provide a phase and/or gain adjusted transformed signal G(Sr(n−i)) which is fed to the combination unit 3, as discussed above.

It is noted that the present invention does not require the use of an impulse response or its Fourier transform for producing reverberation. Instead, the present invention produces reverberation using the delayed transform (for example the Fourier transform) of the signal itself.

In a preferred embodiment, the modification unit 6 applies a random or pseudo-random phase shift relative to the original phase. This has the advantage of decorrelating the signals G(Sr(n−i)) and S(n), which are combined in the combination unit 3. If these signals were correlated, repetitive patterns would occur in the reverberation.

The inverse transform unit 4 performs an inverse transform, typically an Inverse Fast Fourier Transform (IFFT), to produce an output time signal sr(n) that contains reverberation.

It can thus be seen that the device 1 produces reverberation in a very simple and effective manner. By producing reverberation in the transformed (typically: frequency) domain instead of in the time domain, the use of long delay lines is avoided.

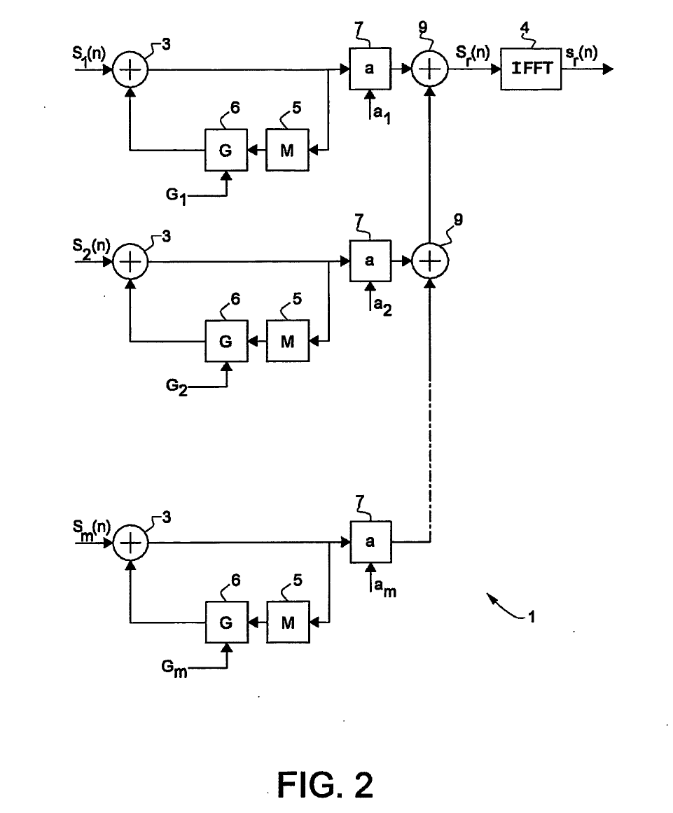

The device 1 of FIG. 1 provides uniform reverberation for the entire signal s(n). It is also possible to provide individual reverberation for separate frequency bands or instruments. Using MDI-technology, individual instruments may be processed separately. An exemplary embodiment of the device 1 of the present invention that allows such separate processing is schematically illustrated in FIG. 2.

In the embodiment of FIG. 2, individual transformed signals (for example frequency spectra) S1(n), S2(n), . . . Sm(n) are received and fed to a respective combination unit 3. These transformed signals may originate from a MIDI data storage, or from a filter bank to which an original (composite) transformed signal S(n) or time signal s(n) is fed. These transformed input signals may be retrieved from a MIDI sound bank or may be synthesized in the frequency domain from a parametric representation of the audio signals in a MIDI sound bank.

The device of FIG. 2 has m parallel branches which each comprise a combination unit 3, a memory unit 5, a gain/phase modification unit 6, and a scaling unit 7. Each branch (except the mth one) also comprises a further combination unit 9 for combining the output signal of the branch concerned with that of the other branches. An inverse transform unit 4 produces a time (output) signal sr(n) containing reverberation, as in the embodiment of FIG. 1.

The advantage of the embodiment of FIG. 2 is that the reverberation can be controlled per instrument or per channel. More in particular, a scaling may be provided by means of the modification units 6, which are preferably arranged for modifying both the phase and the amplitude of the delayed transformed output signals. Each modification unit 6 may have an individual gain G1, G2 . . . , Gm which individual gain serves as a scaling factor and controls the reverberation in the respective branch. The individual gains G1, G2 . . . Gm may be pre-set, user controlled, or extracted from MIDI content.

Further scaling may be provided by means of scaling units 7. Said scaling units 7 may be provided in each branch or in (m-1) branches. Scaling units 7 each receive a scaling factor aj (j=1 . . . m) and multiply the signal Sr(n) by this scaling factor so as to produce a scaled signal aj .Sr(n) which is fed to the respective further combination unit 9. The scaling factors aj determine the relative contribution of each branch to the combined transformed output signal Sr(n).

The scaling units 7 may be integrated in the further combination units 9 so as to form weighted combination units. Additionally, or alternatively, the individual further combination units 9 shown in FIG. 2 may be combined into a single further combination unit having multiple inputs.

The scaling factors aj may also be pre-set, user controlled, or extracted from MIDI content. Embodiments can be envisaged in which scaling units are arranged before the combination units 3 so as to scale the transformed input signals.

In the embodiment of FIG. 2 it has been assumed that the input signals sj(n) are available as transformed signals Sj(n). If this is not the case, suitable transform units (2 in FIG. 1) can be provided.

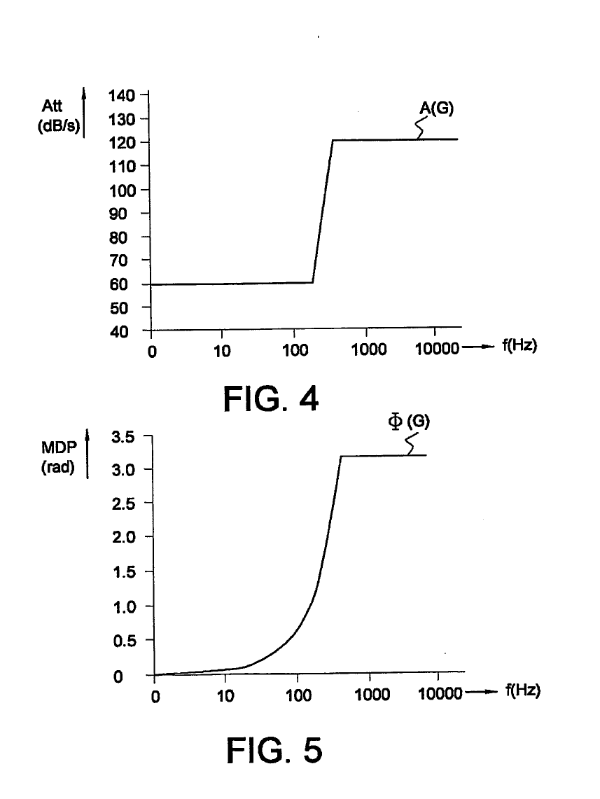

The operation of the gain/phase modification units 6 will be further explained with reference to FIGS. 4 and 5. An exemplary gain A(G) is illustrated in FIG. 4. In this particular example, the gain A(G) is smaller than one and therefore constitutes attenuation (Att), measured in decibels per second (dB/s), as a function of the frequency (f), measured in Hertz (Hz). In the example of FIG. 4, the attenuation is shown to be approximately 60 dB/s for frequencies ranging from 0 to about 200 Hz, and approximately 120 dB/s for frequencies above about 300 Hz. Thus a frequency-dependent gain (that is, attenuation) is provided which controls the reverberation time as a function of the frequency.

The graph of FIG. 5 shows an exemplary maximum phase difference (Maximum Different Phase, MDP), expressed in rad, as a function of the frequency (f), measured in Hertz (Hz). As mentioned above, the gain/phase modification unit 6 produces a substantially random phase. However, in order to avoid signal distortion, the phase is preferably constrained. That is, the phase difference introduced by the gain/phase modification unit 6 is preferably limited to the value Φ(G) shown in FIG. 5. In the example shown, this value is close to zero for frequencies up to about 100 Hz, then rises steeply to a level of p rad, and subsequently maintains this level. Limiting the phase difference introduced by the gain/phase modification unit 6 avoids signal distortion.

An audio system 10 comprising at least one device 1, 1′ of the present invention is schematically illustrated in FIG. 3. The audio system 10 further comprises a windowing (W) unit 11 for applying a time window to a digital (or digitized) signal s(k), where k indicates the sample number, so as to obtain a signal s(n) comprised of frames, where n indicates the frame number. Similarly, a further windowing (W) unit 12 is provided to convert the frames into a regular digital signal. The windowing units 11 and 12 may comprise overlap/add circuits for providing partially overlapping frames.

The audio system may further comprise one or more amplifiers, filters and/or signal processing means (not shown). Suitable D/A (Digital/Analog) converters may be provided for converting the digital output signal into an analog output signal. Similarly, an A/D (Analog/Digital) converter may be provided at the input for converting (that is, digitizing) an analog input signal into a digital input signal. The audio system 10 may further comprise one or more transducers, such as loudspeakers, for producing sound. Additionally, or alternatively, the audio system 10 may comprise one or more sound signal sources, such as a DVD player, a CD player, MIDI storage, and/or an Internet terminal.

The present invention is based upon the insight that reverberation may be generated efficiently using a delayed transformed signal instead of a delayed time signal. The present invention benefits from further insight that the delayed transformed signal should have a substantially random phase.

It is noted that any terms used in this document should not be construed so as to limit the scope of the present invention. In particular, the words “comprise(s)” and “comprising” are not meant to exclude any elements not specifically stated. Single (circuit) elements may be substituted with multiple (circuit) elements or with their equivalents.

1. A device for adding reverberation to an input signal represented by a corresponding transformed input signal, the device comprising:
delay means for delaying the transformed output signal so as to produce a delayed transformed output signal, and
combination means for combining the transformed input signal with a delayed transformed output signal so as to produce a current transformed output signal representing an output signal having reverberation.

2. The device of claim 1, further comprising modification means for modifying the amplitude and/or the phase of the delayed transformed output signal so as to produce a modified and delayed transformed output signal.

3. The device of claim 2, wherein the modification means are arranged for providing a substantially random phase.

4. The device of claim 3, wherein the random phase is bound by a maximum phase differences, said maximum phase difference being substantially smaller than a threshold for low frequencies and substantially equal to said threshold for high frequencies.

5. The device of claim 3, wherein the modification means are arranged for an amplitude adjustment which involves a relatively small attenuation for low frequencies and a relatively large attenuation for higher frequencies.

6. The device of claim 1, comprising multiple parallel branches, each branch being provided with processing means for combining a partial transformed input signal with a modified and delayed transformed partial output signal so as to produce a current transformed partial output signal, the device further comprising at least one further combination unit for combining the transformed partial output signals into a transformed combined output signal.

7. The device of claim 6, wherein at least one branch comprises at least one scaling unit for scaling at least one partial output signal.

8. The device of claim 1, wherein the processing means are arranged for processing the transformed input signal per frame.

9. The device of claim 1, further comprising a transform unit for transforming an input signal into a transformed input signal.

10. An audio system comprising a device claim 1.

11. A method of adding reverberation to an input signal represented by a corresponding transformed input signal, the method comprising:
delaying the transformed output signal so as to produce a delayed transformed output signal, and
combining the transformed input signal with a delayed transformed output signal so as to produce a current transformed output signal representing an output signal having reverberation.

12. A computer program product for carrying out the method claim 11.
